(19) United States
(12) Patent Application Publication
(10) Pub. No.: US 2025/0380495 A1
(43) Pub. Date: Dec. 11, 2025

(54) TRANSISTOR STRUCTURE

(71) Applicant: Excelliance MOS Corporation, Hsinchu County (TW)

(72) Inventors: Pei-Hua Lin, Hsinchu County (TW); Yun-Han Cheng, Hsinchu County (TW); Chu-Kuang Liu, Hsinchu County (TW)

(73) Assignee: Excelliance MOS Corporation, Hsinchu County (TW)

(21) Appl. No.: 18/796,262

(22) Filed: Aug. 6, 2024

(30) Foreign Application Priority Data
Jun. 7, 2024 (TW) 113121319

(51) Int. Cl. H01L 27/088; H01L 27/06; H01L 29/423; H01L 29/49

(52) U.S. Cl. CPC H10D 84/83; H10D 64/513; H10D 64/518; H10D 64/662; H10D 88/00

(57) ABSTRACT

A transistor structure includes an epitaxial layer, a well region, multiple gate regions, multiple first heavily doped regions, and multiple second heavily doped regions. The well region is formed on the epitaxial layer. The gate regions are formed in the epitaxial layer and penetrate the well region. Each of the first heavily doped regions is formed on a first side of the corresponding gate region, and the first heavily doped regions are isolated from each other. Each of the second heavily doped regions is formed on a second side of the corresponding gate region, and the second heavily doped regions are isolated from each other. The first side and the second side are different.

### CROSS-REFERENCE TO RELATED APPLICATION

This application claims the priority benefit of Taiwan application serial no. 113121319, filed on Jun. 7, 2024. The entirety of the above-mentioned patent application is hereby incorporated by reference herein and made a part of this specification.

### BACKGROUND

### Technical Field

The disclosure relates to a transistor structure, and in particular to a transistor structure that can improve thermal stability.

### Description of Related Art

In a transistor structure, as an operating temperature changes, a curve of an operating

current of the transistor structure often changes with the change in temperature. When the operating temperature rises significantly, the operating current provided by a fixed gate-source bias corresponding to the transistor structure may be much greater than the expected operating current, and thermal runaway may occur. The phenomenon is particularly possible to occur in the transistor structure applied in a power transistor. Therefore, how to enable the transistor structure to have good thermal stability is a topic for those skilled in the art.

### SUMMARY

The disclosure provides various transistor structures, which can effectively improve the thermal stability thereof.

A transistor structure of the disclosure includes an epitaxial layer, a well region, multiple gate regions, multiple first heavily doped regions, and multiple second heavily doped regions. The well region is formed on the epitaxial layer. The gate regions are formed in the epitaxial layer and penetrate the well region. Each of the first heavily doped regions is formed on a first side of the corresponding gate region. The first heavily doped regions are isolated from each other. Each of the second heavily doped regions is formed on a second side of the corresponding gate region. The second heavily doped regions are isolated from each other, and the first side and the second side are different.

Another transistor structure of the disclosure includes an epitaxial layer, a well region, multiple gate regions, multiple heavily doped regions, and multiple buried heavily doped regions.

The well region is formed on the epitaxial layer. The gate regions are formed in the epitaxial layer and penetrate the well region. Two of the heavily doped regions are respectively formed on both sides of the corresponding gate region. The buried heavily doped regions are respectively formed in the well regions under multiple selected heavily doped regions among the heavily doped regions.

Based on the above, in the transistor structure of the disclosure, through reducing a transconductance value, a gate-source bias point of the transistor structure is adjusted to operate near a zero temperature coefficient point or greater than the zero temperature coefficient point to allow an operating current to enter a negative temperature coefficient region. Through the above configuration, a current gain of the transistor structure may be reduced, and the possibility of thermal runaway is reduced, thereby improving the thermal stability of the transistor.

### BRIEF DESCRIPTION OF THE DRAWINGS

FIG. 1 shows a characteristic curve of a transistor structure according to an embodiment of the disclosure.

FIG. 2 shows a three-dimensional schematic view of a transistor structure according to an embodiment of the disclosure.

FIG. 3 shows a three-dimensional schematic view of a transistor structure according to another embodiment of the disclosure.

FIG. 4 shows a top schematic view of a transistor structure according to an embodiment of the disclosure.

FIG. 5 shows a three-dimensional schematic view of a transistor structure according to another embodiment of the disclosure.

FIG. 6 shows a schematic view of a cross-sectional structure of a transistor structure 500 based on a line segment A-A′ according to the embodiment of FIG. 5.

FIG. 7 shows a three-dimensional schematic view of a transistor structure according to another embodiment of the disclosure.

FIG. 8A to FIG. 8H respectively show top schematic views of different implementations of a transistor structure according to an embodiment of the disclosure.

### DETAILED DESCRIPTION OF DISCLOSED EMBODIMENTS

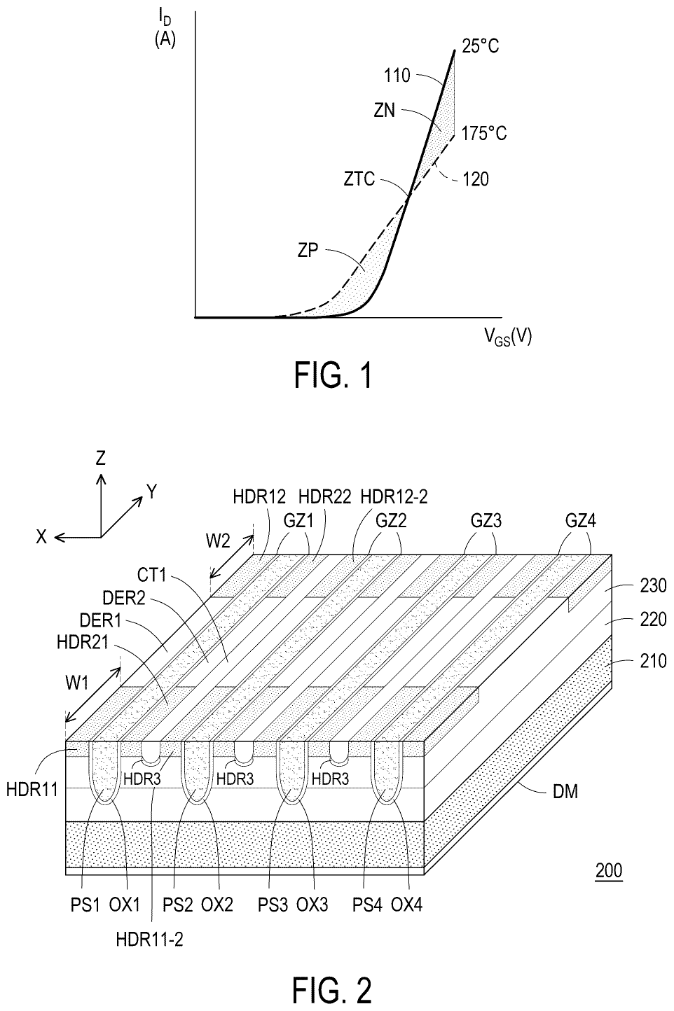

Please refer to FIG. 1. FIG. 1 shows a characteristic curve of a transistor structure according to an embodiment of the disclosure. A vertical axis in FIG. 1 is an operating current (that is, a drain current) I_{D} of the transistor structure in units of amperes (A); a horizontal axis is a gate-source bias V_{GS} thereof in units of volts (V). When the transistor structure is at a room temperature (such as 25° C.), the operating current is a characteristic curve 110. When the transistor structure is at a relatively high temperature (such as 175° C.), the operating current is a characteristic curve 120. An intersection point of the characteristic curve 110 and the characteristic curve 120 may be a zero temperature coefficient point ZTC. Above the zero temperature coefficient point ZTC, a region ZN between the characteristic curve 110 and the characteristic curve 120 may be a negative temperature coefficient region. Below the zero temperature coefficient point ZTC, a region ZP between the characteristic curve 110 and the characteristic curve 120 may be a positive temperature coefficient region.

The following is a current equation of the transistor structure:

$${I}_{D} = \frac{1}{2} {μ}_{n} Cox \frac{W}{L} {( {V}_{GS} - V th )}^{2}$$

In the above equation, μₙ is a carrier mobility, Cox is a unit capacitance value of a gate oxide layer, Vth is a threshold voltage (or a turn-on voltage) of the transistor structure, W is a channel width, L is a channel length, and V_{GS} is a voltage difference between the gate and the source of the transistor structure.

At the same time, according to an equation of transconductance K(T) of the transistor structure:

$$K ( T ) = \frac{{μ}_{0} CoxW}{2 L}$$

In the above equation, μ₀ is the carrier mobility.

In the embodiment of the disclosure, through reducing the transconductance K(T) of the transistor structure, the gate-source bias V_{GS} of the transistor structure is increased, and the bias V_{GS} may be controlled near the zero temperature coefficient point ZTC or the gate-source bias V_{GS} may correspond to the region ZN of the negative temperature coefficient region, so that the temperature stability of the transistor structure when operating is improved.

For technical details of the transistor structure according to an embodiment of the disclosure, reference may be made to the following embodiment.

Please refer to FIG. 2. FIG. 2 shows a three-dimensional schematic view of a transistor structure according to an embodiment of the disclosure. A transistor structure 200 may be a power transistor structure. The transistor structure 200 includes a substrate layer 210, an epitaxial layer 220, a well region 230, multiple gate regions GZ1 to GZ4, heavily doped regions HDR11 and HDR12, heavily doped regions HDR21 and HDR22, a heavily doped region HDR3, and multiple semiconductor structures DER1 and DER2. The epitaxial layer 220 covers the substrate layer 210, and the well region 230 is formed over the epitaxial layer 220. The gate regions GZ1 to GZ4 are formed in the epitaxial layer 220 and the well region 230, and penetrate the well region 230. The substrate layer 210, the epitaxial layer 220, and the well region 230 are sequentially disposed extending upward along a Z-axis direction. The semiconductor structures DER1 and DER2 may have the same material as the well region 230.

The gate regions GZ1 to GZ4 respectively have polysilicon structures PS1 to PS4 and oxide layers OX1 to OX4. The gate regions GZ1 to GZ4 may be sequentially disposed along an X-axis direction. The gate regions GZ1 to GZ4 are formed in the epitaxial layer 220 and penetrate the well region 230. The oxide layers OX1 to OX4 are respectively formed outside the polysilicon structures PS1 to PS4 and respectively surround the polysilicon structures PS1 to PS4. The polysilicon structures PS1 to PS4 are configured to compose a gate structure of the transistor structure 200. The oxide layers OX1 to OX4 are configured to form the gate oxide layer of the gate structure.

Each of the gate regions GZ1 to GZ4 may extend along a Y-axis direction. Each of the polysilicon structures PS1 to PS4 may also extend along the Y-axis direction with each of the corresponding oxide layers OX1 to OX4.

The following takes the gate region GZ1 as an example. The heavily doped regions HDR11 and HDR12 are formed on the well region 230 and are formed on different parts of a first side of the gate region GZ1. The heavily doped regions HDR21 and HDR22 are also formed on the well region 230 and are formed on different parts of a second side of the gate region GZ1. In addition, the semiconductor structure DER1 is disposed on the first side of the gate region GZ1 and is disposed between the heavily doped regions HDR11 and HDR12, so that the heavily doped regions HDR11 and HDR 12 are isolated from each other. The semiconductor structure DER2 is disposed on the second side of the gate region GZ1 and is disposed between the heavily doped regions HDR21 and HDR22, so that the heavily doped regions HDR21 and HDR22 are isolated from each other.

In the embodiment, the heavily doped regions HDR11 and HDR12 respectively have a width W1 and a width W2 along the Y-axis direction. A sum of the width W1 and the width W2 may be provided as a channel width of the transistor structure 200 when turned on. Correspondingly, the heavily doped regions HDR21 and HDR22 may respectively have the same width W1 and the same width W2 as the heavily doped regions HDR11 and HDR 12 along the Y-axis direction.

The sum of the width W1 and the width W2 may be provided as the channel width of the transistor structure 200 when turned on. The sum of the width W1 and the width W2 may be less than a total width of the gate region GZ1 in the Y-axis direction. In other words, in the embodiment, through respectively disposing the semiconductor structures DER1 and DER2 in the heavily doped regions HDR11 and HDR12 and the heavily doped regions HDR21 and HDR22, a total channel width that the transistor structure 200 may provide when turned on may be reduced, and by reducing a transconductance value of the transistor structure, a gate-source bias of the transistor structure may operate at a position near the zero temperature coefficient point to reduce a current gain, thereby improving the temperature stability of the transistor structure.

In the embodiment, the width W1 and the width W2 may be the same or different.

Incidentally, in the embodiment of the disclosure, a contact CT1 may be disposed between the two adjacent doped regions HDR22 and HDR12-2 and between the two adjacent doped regions HDR21 and HDR11-2, and covers the doped region HDR3. In the embodiment, a conductive polarity of the doped region HDR3 may be opposite to conductive polarities of the doped regions HDR22, HDR12-2, HDR21, and HDR11-2. The conductive polarities of the doped regions HDR11, HDR12, HDR21, HDR22, HDR12-2, and HDR11-2 may be all the same (such as N⁺). The conductive polarity of the doped region HDR3 may be P⁺.

In addition, in the embodiment, the substrate layer 210 may be an N⁺-type substrate layer, the epitaxial layer 220 may be an N⁻-type epitaxial layer, and the well region 230 may be a P-type well region.

In the embodiment, the doped regions HDR11, HDR12, HDR21, HDR22, HDR12-2, and HDR11-2 may be configured to form the source of the transistor structure 200. The substrate layer 210 may be coupled to a metal layer DM serving as a drain of the transistor structure 200.

Incidentally, in the embodiment of the disclosure, there is no fixed limit to the number of the gate regions GZ1 to GZ4 that may be disposed in the transistor structure 200. FIG. 2 only shows an example for descriptions and is not intended to limit the scope of the disclosure.

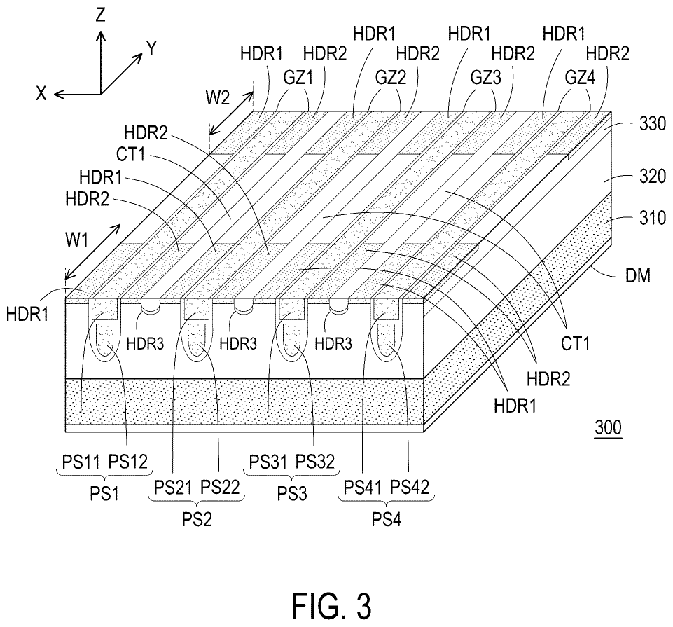

Referring to FIG. 3, FIG. 3 shows a three-dimensional schematic view of a transistor structure according to another embodiment of the disclosure. A transistor structure 300 includes a substrate layer 310, an epitaxial layer 320, a well region 330, multiple gate regions GZ1 to GZ4, a contact CT1, and multiple heavily doped regions HDR1, HDR2, and HDR3. The transistor structure 300 has a similar architecture to the transistor structure 200 of the foregoing embodiment, wherein the same parts are not described in detail here.

Different from the foregoing embodiment, in the transistor structure 300, polysilicon structures PS1 to PS4 in the gate regions GZ1 to GZ4 respectively have first substructures PS11 to PS41 and second substructures PS12 to PS42. The first substructures PS11 to PS41 and the second substructures PS12 to PS42 may respectively overlap each other and form a split gate structure. The first substructures PS11 to PS41 and the second substructures PS12 to PS42 may respectively be isolated from each other through an oxide layer.

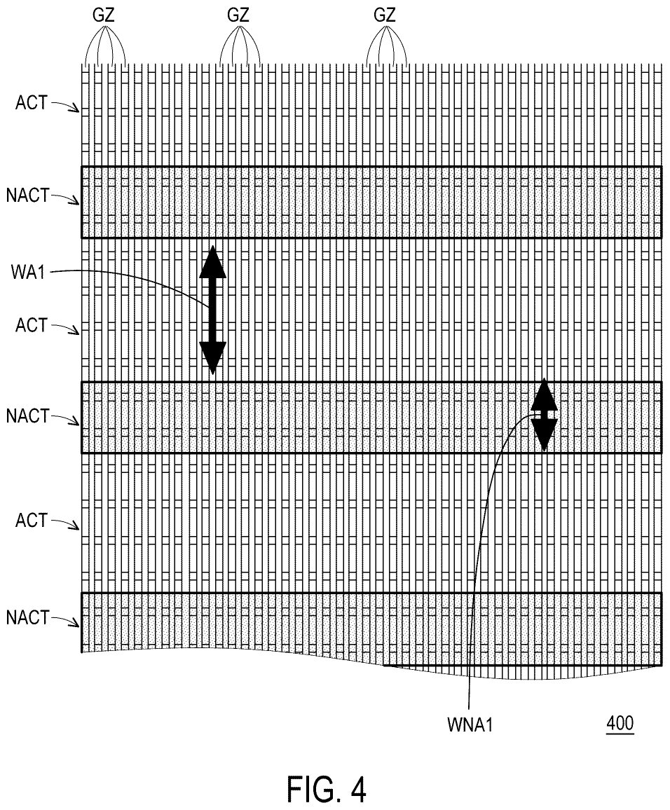

Referring to FIG. 4, FIG. 4 shows a top schematic view of a transistor structure according to an embodiment of the disclosure. In a transistor structure 400, multiple gate regions are disposed parallel to each other. According to descriptions of the embodiment of FIG. 2, through disposing semiconductor structures of non-heavily doped regions on both sides of the gate region GZ in the embodiment of the disclosure, multiple non-active regions NACT may be correspondingly generated. In addition, through disposing heavily doped regions on both sides of the gate region GZ, multiple active regions ACT may be correspondingly generated. Each of the non-active regions NACT may have a width WNA1, and each of the active regions ACT may have a width WA1. The width WA1 may be greater than, less than, or equal to the width WNA1.

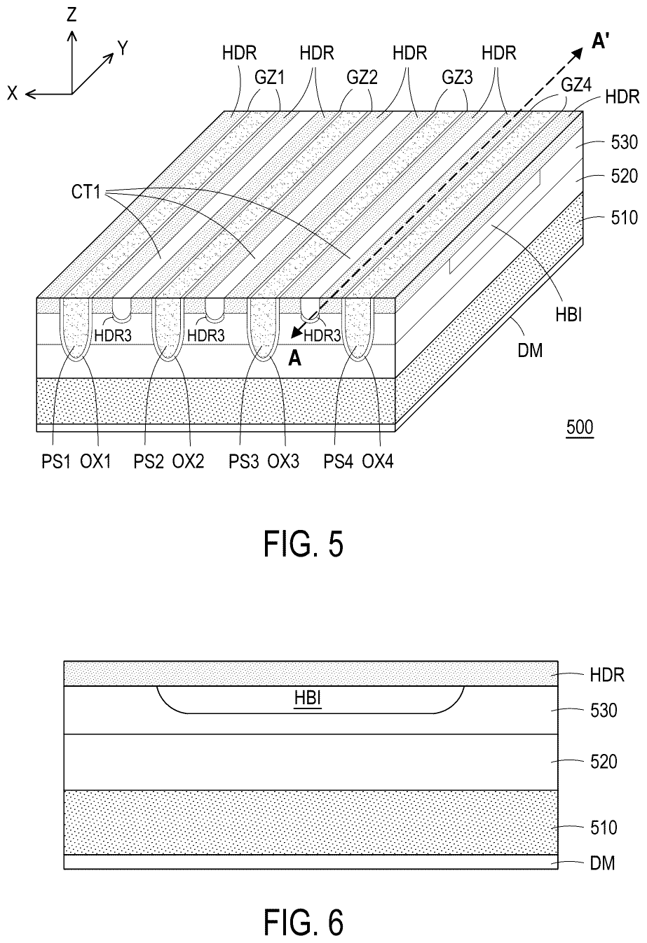

Referring to FIG. 5, FIG. 5 shows a three-dimensional schematic view of a transistor structure according to another embodiment of the disclosure. A transistor structure 500 may be a power transistor structure. The transistor structure 500 includes a substrate layer 510, an epitaxial layer 520, a well region 530, gate regions GZ1 to GZ4, a contact CT1, heavily doped regions HDR and HDR3, and a buried heavily doped region HBI. The epitaxial layer 520 covers the substrate layer 510, and the well region 530 is formed over the epitaxial layer 520. The gate regions GZ1 to GZ4 are formed in the epitaxial layer 520 and the well region 530 and penetrate the well region 530. The substrate layer 510, the epitaxial layer 520, and the well region 530 are sequentially disposed extending upward along the Z-axis direction. A bottom part of the substrate layer 510 is coupled to a metal layer DM, and the metal layer DM may be configured as a drain of the transistor structure 500.

The gate regions GZ1 to GZ4 may be sequentially disposed along the X-axis direction, formed in the epitaxial layer 520, and penetrate the well region 530. The gate regions GZ1 to GZ4 respectively have polysilicon structures PS1 to PS4 and oxide layers OX1 to OX4. The oxide layers OX1 to OX4 are respectively formed outside the polysilicon structures PS1 to PS4 and respectively surround the polysilicon structures PS1 to PS4. The polysilicon structures PS1 to PS4 are configured to compose a gate structure of the transistor structure 500. The oxide layers OX1 to OX4 are configured to form a gate oxide layer of the gate structure.

Each of the gate regions GZ1 to GZ4 may extend along the Y-axis direction. Each of the polysilicon structures PS1 to PS4 may also extend along the Y-axis direction with each of the corresponding oxide layers OX1 to OX4.

The heavily doped regions HDR are respectively disposed on sides of the gate regions GZ1 to GZ4 and are configured to form a source of the transistor structure 500. The heavily doped regions HDR3 may be disposed under the contact CT1, and a conductive type of the heavily doped regions HDR3 may be opposite to the conductive type of the heavily doped region HDR.

It is worth noting that in the embodiment, part of the heavily doped regions HDR may be set as selected heavily doped regions. The buried heavily doped region HBI buried in the well region 530 may be formed under the selected heavily doped regions. After disposing the buried heavily doped region HBI, a current equation of the transistor structure 500 may be rewritten as:

$${I}_{D} = K ( T ) {( {V}_{GS} - V th )}^{2} = {K ( T )}_{1} {( {V}_{GS} - V th )}^{2} + {K ( T )}_{2} {( {V}_{GS} - V th 2 )}^{2}$$

In the above equation, K(T)₁ is a transconductance value excluding the buried heavily doped region HBI, K(T)₂ is a transconductance value including the buried heavily doped region HBI, Vth2 and Vth1 are respectively threshold voltages (or turn-on voltages) of parts of the transistor structure with or without the buried heavily doped region HBI, and V_{GS} is a voltage difference between the gate and the source of the transistor structure 500.

From the above descriptions, it can be seen that through disposing the buried heavily doped region HBI, the equivalent transconductance value K(T) may be reduced, and a gate-source bias may be controlled near the zero temperature coefficient point or the gate-source bias may correspond to a region of the negative temperature coefficient region, so that the temperature stability of the transistor structure when operating is improved.

It is worth noting that in the embodiment, since the buried heavily doped region HBI disposed may still provide a capability for current flow, an increase in a turn-on resistance value caused by the transistor structure 500 of the embodiment during a process of adjusting the transconductance value may be effectively controlled, so that the increase is not excessive to maintain operating efficiency of the transistor structure 500.

Please note here that in the transistor structure 500 of the embodiment, the buried heavily doped region HBI does not need to be disposed under all of the heavily doped regions HDR. A designer may decide the number of selected heavily doped regions according to a level of the gate-source bias to be adjusted.

Referring to FIG. 6, FIG. 6 shows a schematic view of a cross-sectional structure of the transistor structure 500 based on a line segment A-A′ according to the embodiment of FIG. 5. The substrate layer 510 is coupled to and covers the metal layer DM configured as the drain of the transistor structure 500. The epitaxial layer 520 covers the substrate layer 510. The well region 530 covers the epitaxial layer 520, and the heavily doped region HDR covers the well region 530. When the heavily doped region HDR is the selected heavily doped region, the buried heavily doped region HBI may be formed under the heavily doped region HDR. The buried heavily doped region HBI and the heavily doped region HDR are electrically coupled to each other, wherein the buried heavily doped region HBI is formed in the well region 530.

In the embodiment, the substrate layer 510 may be an N⁺-type substrate, the epitaxial layer 520 may be an N-type epitaxial layer, the well region 530 may be a P-type well region, and the heavily doped region HDR may be an N⁺-type heavily doped region.

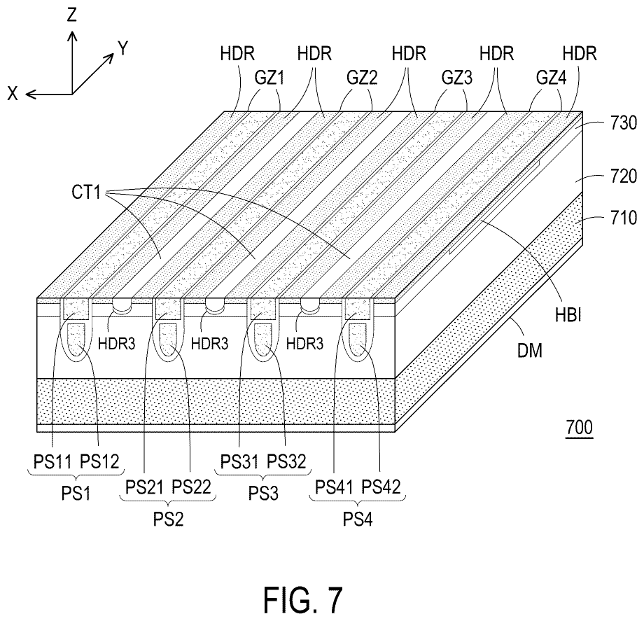

Referring to FIG. 7, FIG. 7 shows a three-dimensional schematic view of a transistor structure according to another embodiment of the disclosure. A transistor structure 700 may be a power transistor structure. The transistor structure 700 includes a substrate layer 710, an epitaxial layer 720, a well region 730, gate regions GZ1 to GZ4, a contact CT1, heavily doped regions HDR and HDR3, and a buried heavily doped region HBI.

The transistor structure 700 has a similar architecture to the transistor structure 500 of the foregoing embodiment, wherein the same parts are not described in detail here.

Different from the foregoing embodiment, in the transistor structure 700, polysilicon structures PS1 to PS4 in the gate regions GZ1 to GZ4 respectively have first substructures PS11 to PS41 and second substructures PS12 to PS42. The first substructures PS11 to PS41 and the second substructures PS12 to PS42 may respectively overlap each other and form a split gate structure. The first substructures PS11 to PS41 and the second substructures PS12 to PS42 may respectively be isolated from each other through an oxide layer.

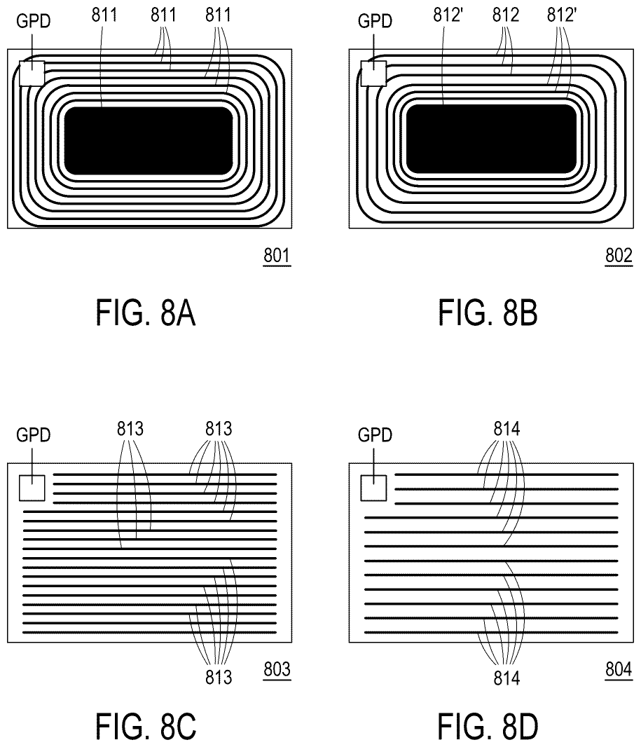

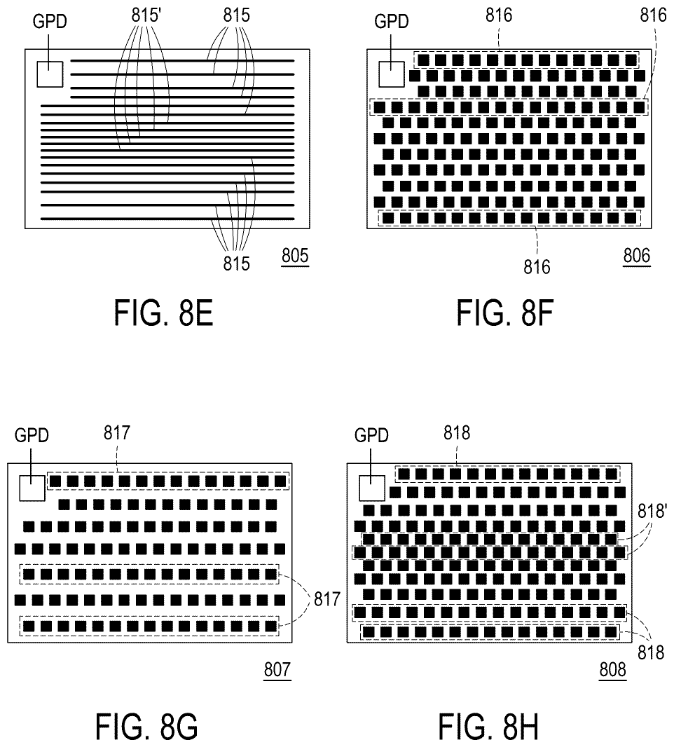

Please refer to FIG. 8A to FIG. 8H. FIG. 8A to FIG. 8H respectively show top schematic views of different implementations of a transistor structure according to an embodiment of the disclosure. In FIG. 8A to FIG. 8H, transistor structures 801 to 808 may have the same architecture as the transistor structures 200, 300, 500, or 700. In FIG. 8A, when the transistor structure 801 has the same architecture as the transistor structure 200 or 300, a structure 811 may be a non-active region of the transistor structure 801. The structure 811 may be annularly disposed in the transistor structure 801.

When the transistor structure 801 has the same architecture as the transistor structure 500 or 700, the structure 811 may be a buried heavily doped region (HBI) therein. In the same way, the structure 811 may be annularly disposed in the transistor structure 801.

Incidentally, the transistor structure 801 has a gate pad GPD configured to be electrically coupled to each gate region in the transistor structure 801 through a transmission wire (not shown).

In FIG. 8B, when the transistor structure 802 has the same architecture as the transistor structure 200 or 300, structures 812 and 812′ may be non-active regions of the transistor structure 802 and are annularly disposed on the transistor structure 802.

Similarly, when the transistor structure 802 has the same architecture as the transistor structure 500 or 700, the structures 812 and 812′ may be buried heavily doped regions (HBI) of the transistor structure 802 and are annularly disposed on the transistor structure 802.

In the embodiment, the structure 812 is formed in a peripheral region of the transistor structure 802, and the structure 812′ is formed in a central region of the transistor structure 802. In the embodiment, a distribution of the structures 812 has a second density, and a distribution of the structures 812′ has a first density. The first density is greater than or equal to the second density.

In practical applications, when a decapping action is performed on the transistor structure, a burn mark caused by overheating may be found to easily occur in the central region of the transistor structure. Therefore, through increasing a distribution density of the structures 812′ in the central region of the transistor structure 802, a current magnitude in the central region of the transistor structure 802 may be reduced to reduce a temperature of the central region of the transistor structure.

In FIG. 8C, when the transistor structure 803 has the same architecture as the transistor structure 200 or 300, a structure 813 may be a non-active region of the transistor structure 803 and is linearly disposed on the transistor structure 803. Similarly, when the transistor structure 803 has the same architecture as the transistor structure 500 or 700, the structure 813 may be a buried heavily doped region (HBI) of the transistor structure 803 and is linearly disposed on the transistor structure 803.

In FIG. 8D, when the transistor structure 804 has the same architecture as the transistor structure 200 or 300, a structure 814 may be a non-active region of the transistor structure 804 and is linearly disposed on the transistor structure 804. Similarly, when the transistor structure 804 has the same architecture as the transistor structure 500 or 700, the structure 814 may be a buried heavily doped region (HBI) of the transistor structure 804 and is linearly disposed on the transistor structure 804.

In FIG. 8C and FIG. 8D, in the transistor structures 803 and 804, the structures 813 and 814 are all linearly and uniformly disposed in the transistor structures 803 and 804. In the transistor structures 803 and 804, distribution densities of the structures 813 and 814 may be different. It is worth noting that in the embodiment of the disclosure, through adjusting the distribution densities of the structures 813 and 814 on the transistor structures 803 and 804, current output densities may be adjusted, and a uniformity of a transistor temperature can be improved.

In FIG. 8E, when the transistor structure 805 has the same architecture as the transistor structure 200 or 300, structures 815 and 815′ may be non-active regions of the transistor structure 805 and are linearly disposed on the transistor structure 805. Similarly, when the transistor structure 805 has the same architecture as the transistor structure 500 or 700, the structures 815 and 815′ may be buried heavily doped regions (HBI) of the transistor structure 805 and are linearly disposed on the transistor structure 805.

Incidentally, the structure 815 is disposed in a peripheral region of the transistor structure 805, and the structure 815′ is disposed in a central region of the transistor structure 805. In the embodiment, a density of the structures 815 disposed in the peripheral region may be less than or equal to a density of the structures 815′ disposed in the central region.

In FIG. 8F and FIG. 8G, in the transistor structures 806 and 807, structures 816 and 817 are all uniformly disposed in a form of multiple sub-blocks in the transistor structures 806 and 807. When the transistor structures 806 and 807 have the same architecture as the transistor structure 200 or 300, the structures 816 and 817 may be non-active regions of the transistor structures 806 and 807. When the transistor structures 806 and 807 have the same architecture as the transistor structure 500, the structures 816 and 817 may respectively be buried heavily doped regions (HBI) of the transistor structures 806 and 807.

In the transistor structures 806 and 807, distribution densities of the structures 816 and 817 may be different. It is worth noting that in the embodiment of the disclosure, through adjusting the distribution densities of the structures 816 and 817 on the transistor structures 806 and 807, current input densities may be adjusted, and a uniformity of a transistor temperature can be improved.

In FIG. 8H, in the transistor structure 808, structures 818 and 818′ are also disposed in a form of multiple sub-blocks. The structures 818 are distributed in a peripheral region of the transistor structure 808, and the structures 818′ are distributed in a central region of the transistor structure 808. A distribution density of the structures 818 may be lower than or equal to a distribution density of the structures 818′.

Similar to the foregoing embodiment, when the transistor structure 808 has the same architecture as the transistor structures 200 or 300, the structures 818 and 818′ may be non-active regions of the transistor structure 808. When the transistor structure 808 has the same architecture as the transistor structures 500 or 700, the structures 818 and 818′ may respectively be buried heavily doped region HBI of the transistor structure 808.

In summary, in the transistor structure according to the embodiment of the disclosure, the gate-source bias of the transistor structure is adjusted through lowering the transconductance value. The current gain of the operating current of the transistor structure corresponding to the temperature is reduced, and the possibility of thermal runaway is effectively reduced, thereby improving the thermal stability of the transistor.

What is claimed is:

1. A transistor structure, comprising:
an epitaxial layer;
a well region, formed on the epitaxial layer;
a plurality of gate regions, formed in the epitaxial layer and penetrating the well region;
a plurality of first heavily doped regions, wherein each of the plurality of first heavily doped regions is formed on a first side of the corresponding gate region, and the plurality of first heavily doped regions are isolated from each other; and
a plurality of second heavily doped regions, wherein each of the plurality of second heavily doped regions is formed on a second side of the corresponding gate region, the plurality of second heavily doped regions are isolated from each other, and the first side and the second side are different.

2. The transistor structure according to claim 1, further comprising:
a plurality of first semiconductor structures, wherein each of the plurality of first semiconductor structures is formed between corresponding two of the plurality of first heavily doped regions; and
a plurality of second semiconductor structures, wherein each of the plurality of second semiconductor structures is formed between corresponding two of the plurality of second heavily doped regions,
wherein the plurality of first semiconductor structures, the plurality of second semiconductor structures, and the well region have a same material.

3. The transistor structure according to claim 1, further comprising:
a substrate layer, wherein the epitaxial layer is formed on the substrate layer.

4. The transistor structure according to claim 1, wherein the well region has a first conductive polarity, each of the plurality of first heavily doped regions and each of the plurality of second heavily doped regions have a second conductive polarity, and the first conductive polarity is opposite to the second conductive polarity.

5. The transistor structure according to claim 1, wherein each of the plurality of gate regions comprises:
a polysilicon structure, formed in the epitaxial layer and penetrating the well region, and configured to form a gate structure; and
an oxide layer, formed outside the polysilicon structure and surrounding the polysilicon structure.

6. The transistor structure according to claim 5, wherein the polysilicon structure comprises:
a first substructure; and
a second substructure,
wherein the first substructure and the second substructure overlap each other and form a split gate structure.

7. The transistor structure according to claim 1, wherein the plurality of first heavily doped regions and the plurality of second heavily doped regions form a source of the transistor structure.

8. The transistor structure according to claim 1, wherein each of the plurality of gate regions, each of the plurality of first heavily doped regions, and each of the plurality of second heavily doped regions form a ring-shaped structure.

9. The transistor structure according to claim 1, wherein a distribution of the plurality of first heavily doped regions and the plurality of second heavily doped regions in a central region has a first density, and a distribution of the plurality of first heavily doped regions and the plurality of second heavily doped regions in a peripheral region has a second density, wherein the first density is greater than or equal to the second density.

10. The transistor structure according to claim 1, further comprising:
a plurality of third heavily doped regions, wherein each of the plurality of third heavily doped regions is formed between each of the plurality of first heavily doped regions and each of the plurality of second heavily doped regions that are adjacent to each other.

11. A transistor structure, comprising:
an epitaxial layer;
a well region, formed on the epitaxial layer;
a plurality of gate regions, formed in the epitaxial layer and penetrating the well region;
a plurality of heavily doped regions, wherein two of the plurality of heavily doped regions are respectively formed on both sides of the corresponding gate region; and
a plurality of buried heavily doped regions, respectively formed in a plurality of the well regions under a plurality of selected heavily doped regions among the plurality of heavily doped regions.

12. The transistor structure according to claim 11, wherein a distribution of the plurality of buried heavily doped regions in a central region has a first density, and a distribution of the plurality of buried heavily doped regions in a peripheral region has a second density, wherein the first density is greater than or equal to the second density.

13. The transistor structure according to claim 11, wherein each of the plurality of buried heavily doped regions has a plurality of sub-blocks, and the plurality of sub-blocks do not contact each other.

14. The transistor structure according to claim 11, wherein each of the plurality of gate regions, each of the plurality of heavily doped regions, and each of the plurality of buried heavily doped regions form a ring-shaped structure.

15. The transistor structure according to claim 11, further comprising:
a substrate layer, wherein the epitaxial layer is formed on the substrate layer.

16. The transistor structure according to claim 11, wherein the well region has a first conductive polarity, each of the plurality of heavily doped regions has a second conductive polarity, and the first conductive polarity is opposite to the second conductive polarity.

17. The transistor structure according to claim 11, wherein each of the plurality of gate regions comprises:
a polysilicon structure, formed in the epitaxial layer and penetrating the well region, and configured to form a gate structure; and
an oxide layer, formed outside the polysilicon structure and surrounding the polysilicon structure.

18. The transistor structure according to claim 17, wherein the polysilicon structure comprises:
a first substructure; and
a second substructure,
wherein the first substructure and the second substructure overlap each other and form a split gate structure.

19. The transistor structure according to claim 11, further comprising:
a plurality of third heavily doped regions, wherein each of the plurality of third heavily doped regions is formed between adjacent two of the plurality of heavily doped regions.
